(19) United States
(12) Patent Application Publication
(10) Pub. No.: US 2021/0259111 A1
(43) Pub. Date: Aug. 19, 2021

(54) LAMINATED SHEET

(71) Applicant: NITTO DENKO CORPORATION, Osaka (JP)

(72) Inventors: Keisuke OKUMURA, Osaka (JP); Yoshihiro FURUKAWA, Osaka (JP)

(73) Assignee: NITTO DENKO CORPORATION, Osaka (JP)

(21) Appl. No.: 17/174,993

(22) Filed: Feb. 12, 2021

(30) Foreign Application Priority Data
Feb. 17, 2020 (JP) 2020-024312

(51) Int. Cl. H05K 1/16; H05K 1/03

(52) U.S. Cl. CPC H05K 1/165; H05K 1/03; H05K 2201/0175; H05K 2201/0162; H05K 2201/0154

(57) ABSTRACT

A laminated sheet includes a sheet-shaped inductor including a plurality of wirings and a magnetic layer embedding the plurality of wirings, and a mark formable layer disposed on one surface in a thickness direction of the inductor.

### CROSS REFERENCE TO RELATED APPLICATION

The present application claims priority from Japanese Patent Application No. 2020-024312 filed on Feb. 17, 2020, the contents of which are hereby incorporated by reference into this application.

### TECHNICAL FIELD

The present invention relates to a laminated sheet.

### BACKGROUND ART

Conventionally, it has been known that a sheet-shaped inductor is mounted on an electronic device. As such an inductor, an inductor including a wiring, and a magnetic layer covering the wiring has been proposed (ref: for example, Patent Document 1 below).

### PRIOR ART DOCUMENT

### Patent Document

Patent Document 1Japanese Unexamined Patent Publication No. 2019-220618

### SUMMARY OF THE INVENTION

### Problems to be Solved by the Invention

However, a via for electrically connecting the wiring to the electronic device may be formed in the magnetic layer. At that time, in order to accurately recognize the position of the wiring when viewed from the top, it is necessary to align the inductor. However, in Patent Document 1, there is a problem that the inductor cannot be accurately aligned.

Further, as for the inductor to be mounted on the electronic device, there is a demand that the user wishes to acquire information about it before mounting. However, the inductor of Patent Document 1 does not include the above-described information. Therefore, there is a problem that the user cannot obtain the information of the inductor in advance.

The present invention provides a laminated sheet that is capable of being accurately aligned to form a via, or reliably obtaining information about a product.

### Solution to the Problems

The present invention (1) includes a laminated sheet including a sheet-shaped inductor including a plurality of wirings and a magnetic layer embedding the plurality of wirings, and a mark formable layer disposed on one surface in a thickness direction of the inductor.

The laminated sheet includes the mark formable layer. Therefore, when a mark is formed in the mark formable layer, it is possible to form a via by aligning the laminated sheet based on a mark, or reliably obtain information by recognizing the information about a product based on the mark.

The present invention (2) includes the laminated sheet described in (1), wherein a material for the mark formable layer is a resin composition.

In the laminated sheet, since the material for the mark formable layer is the resin composition, it is easy to form the mark.

The present invention (3) includes the laminated sheet described in (2), wherein the resin composition is a thermosetting resin composition, and satisfies at least one test of the following test (a) to test (e).

Test (a): the laminated sheet is trimmed into a 3 cm square piece to fabricate a sample, and the relative permeability μ1 thereof at a frequency of 10 MHz is determined. Thereafter, the sample is immersed in 200 mL of copper sulfate plating solution containing 66 g/L of copper sulfate pentahydrate, 180 g/L of sulfuric acid concentration, 50 ppm of chlorine, and Top Lutina alpha at 25° C. for 120 minutes, and thereafter, the relative permeability μ2 of the sample at a frequency of 10 MHz is determined. By the following formula, a rate of change of the magnetic permeability before and after the immersion is determined. As a result, the rate of change of the magnetic permeability of the sample is 5% or less.

Rate of Change of Magnetic Permeability (%)=|μ1-μ2|/μ1×100

Test (b): the laminated sheet is trimmed into a 3 cm square piece to fabricate a sample, and the relative permeability μ3 thereof at a frequency of 10 MHz is determined. Thereafter, the sample is immersed in 200 mL of an acid active aqueous solution containing 55 g/L of sulfuric acid at 25° C. for 1 minute, and thereafter, the relative permeability μ4 of the sample at a frequency of 10 MHz is determined. By the following formula, a rate of change of the magnetic permeability before and after the immersion is determined. As a result, the rate of change of the magnetic permeability of the sample is 5% or less.

Rate of Change of Magnetic Permeability (%)=|μ3-μ4|/μ3×100

Test (c): the laminated sheet is trimmed into a 3 cm square piece to fabricate a sample, and the relative permeability μ5 thereof at a frequency of 10 MHz is determined. Thereafter, the sample is immersed in 200 mL of Reduction Solution Securiganth P manufactured by Atotech Japan K.K. at 45° C. for 5 minutes, and thereafter, the relative permeability μ6 of the sample at a frequency of 10 MHz is determined. By the following formula, a rate of change of the magnetic permeability before and after the immersion is determined. As a result, the rate of change of the magnetic permeability of the sample is 5% or less.

Rate of Change of Magnetic Permeability (%)=|μ5-μ6|/μ5×100

Test (d): the laminated sheet is trimmed into a 3 cm square piece to fabricate a sample, and the relative permeability μ7 thereof at a frequency of 10 MHz is determined. Thereafter, the sample is immersed in 200 mL of Concentrate Compact CP manufactured by Atotech Japan K.K. at 80° C. for 15 minutes, and thereafter, the relative permeability μ8 of the sample at a frequency of 10 MHz is determined. By the following formula, a rate of change of the magnetic permeability before and after the immersion is determined. As a result, the rate of change of the magnetic permeability of the sample is 5% or less.

Rate of Change of Magnetic Permeability (%)=|μ7-μ8|/μ7×100

Test (e): the laminated sheet is trimmed into a 3 cm square piece to fabricate a sample, and the relative permeability μ9 thereof at a frequency of 10 MHz is determined. Thereafter, the sample is immersed in 200 mL of Swelling Dip Securiganth P manufactured by Atotech Japan K.K. at 60° C. for 5 minutes, and thereafter, the relative permeability μ10 of the sample at a frequency of 10 MHz is determined. By the following formula, a rate of change of the magnetic permeability before and after the immersion is determined. As a result, the rate of change of the magnetic permeability of the sample is 5% or less.

Rate of Change of Magnetic Permeability (%)=|μ19-μ10|/μ9×100

Since the laminated sheet satisfies at least one test of the test (a) to test (e), it is excellent in stability with respect to process processing using a chemical solution.

### Effect of the Invention

The laminated sheet of the present invention can be accurately aligned to form a via, or reliably obtain information about a product.

### BRIEF DESCRIPTION OF THE DRAWINGS

FIGS. 1A to 1C show plan views for illustrating a producing step of one embodiment of a laminated sheet of the present invention, and a processing embodiment thereof:

FIG. 1A illustrating a laminated sheet,

FIG. 1B illustrating a step of forming a mark, and

FIG. 1C illustrating a step of forming a via.

FIGS. 2A to 2D show front cross-sectional views for illustrating a producing step of one embodiment of a laminated sheet of the present invention, and a processing embodiment thereof:

FIG. 2A illustrating an inductor,

FIG. 2B illustrating a laminated sheet,

FIG. 2C illustrating a step of forming a mark, and

FIG. 2D illustrating a step of forming a via.

FIG. 3 shows an enlarged cross-sectional view of a modified example of a mark.

FIG. 4 shows an enlarged cross-sectional view of a modified example of a mark.

FIG. 5 shows an enlarged cross-sectional view of a modified example of a mark.

FIG. 6 shows a plan view of a modified example of a mark.

FIG. 7 shows a plan view of a modified example (modified example in which a mark is a lot number) of a mark-including laminated sheet shown in FIG. 1B.

### EMBODIMENT OF THE INVENTION

<One Embodiment>

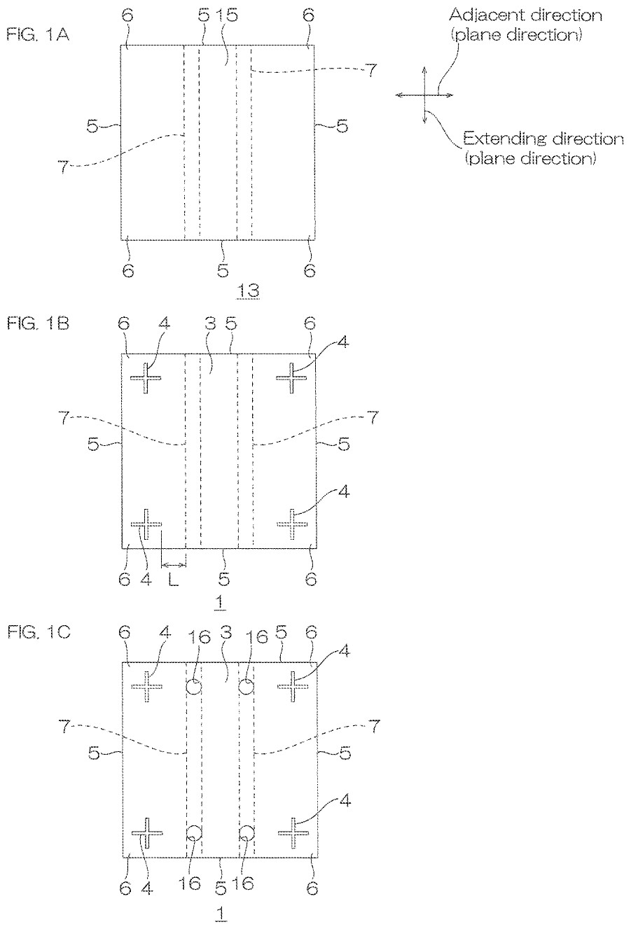

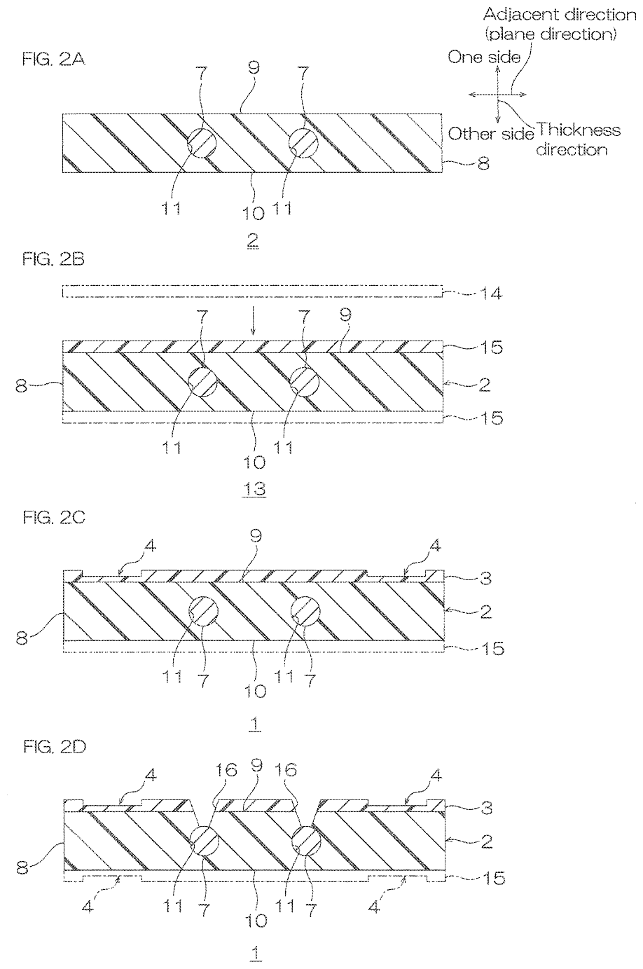

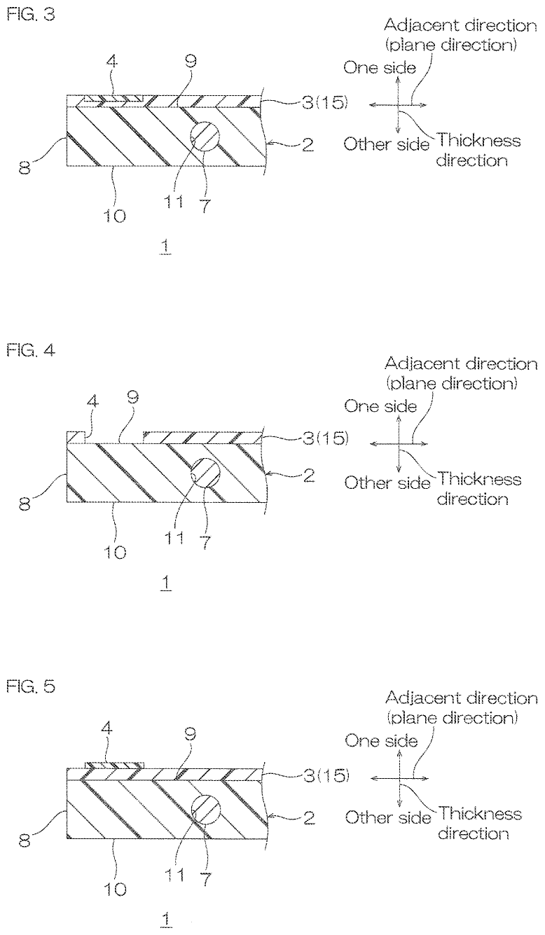

One embodiment of a laminated sheet of the present invention is described with reference to FIGS. 1A and 2B.

A laminated sheet 13 has a predetermined thickness, and has a sheet shape extending in a plane direction perpendicular to a thickness direction. For example, the laminated sheet 13 has a generally rectangular shape when viewed from the top. The laminated sheet 13 includes a sheet-shaped inductor 2, and a mark formable layer 15.

The inductor 2 has the same outer shape as the laminated sheet 13 when viewed from the top. Specifically, the inductor 2 has a generally rectangular shape including four sides 5 when viewed from the top.

Further, the inductor 2 includes a plurality of wirings 7 and a magnetic layer 8.

The plurality of wirings 7 are adjacent to each other at spaced intervals. The plurality of wirings 7 are parallel with each other. The plurality of wirings 7 extend along a direction perpendicular to a direction in which the plurality of wirings 7 are adjacent to each other and the thickness direction. A shape, a dimension, a configuration, a material, and a formulation (filling rate, content ratio, or the like) of the wiring 7 are, for example, described in Japanese Unexamined Patent Publication No. 2019-220618 or the like. Preferably, the wiring 7 has a generally circular shape when viewed in the cross section along a direction perpendicular to a direction along the wiring 7, and the lower limit of the diameter thereof is, for example, 25 μm, and the upper limit of the diameter thereof is, for example, 2,000 μm. The wiring 7 preferably includes a conducting wiring made of a conductor, and an insulating film covering a peripheral surface of the conducting wiring. The lower limit of an interval between the wirings 7 adjacent to each other is, for example, 10 μm, preferably 50 μm, and the upper limit of an interval between the wirings 7 adjacent to each other is, for example, 5,000 μm, preferably 3,000 μm. The upper limit of a ratio (diameter/interval) of the diameter of the wiring 7 to the interval between the wirings 7 adjacent to each other is, for example, 200, preferably 50, and the lower limit thereof is, for example, 0.01, preferably 0.1.

The magnetic layer 8 improves the inductance of the laminated sheet 13. The magnetic layer 8 has the same outer shape as the inductor 2 when viewed from the top. The magnetic layer 8 has a plate shape extending in the plane direction. Further, the magnetic layer 8 embeds the plurality of wirings 7 when viewed in the cross-sectional view. The magnetic layer 8 has a one surface 9, an other surface 10, and an inner peripheral surface 11.

The one surface 9 forms one surface in the thickness direction of the magnetic layer 8.

The other surface 10 forms the other surface in the thickness direction of the magnetic layer 8. The other surface 10 is spaced apart from the other side in the thickness direction of the one surface 9.

The inner peripheral surface 11 is spaced apart from the one surface 9 and the other surface 10 in the thickness direction. The inner peripheral surface 11 is located between the one surface 9 and the other surface 10 in the thickness direction. The inner peripheral surface 11 is located between two outer-side surfaces 18 facing each other in a direction in which the plurality of wirings 7 are adjacent to each other. The inner peripheral surface 11 is in contact with the outer peripheral surface of the wiring 7.

The magnetic layer 8 contains a binder and magnetic particles. Specifically, a material for the magnetic layer 8 is a magnetic composition containing the binder and the magnetic particles.

Examples of the binder include thermoplastic resins such as an acrylic resin and thermosetting resins such as an epoxy resin composition. The acrylic resin includes, for example, a carboxyl group-including acrylic acid ester copolymer. The epoxy resin composition includes, for example, an epoxy resin (cresol novolac epoxy resin or the like) as a main agent, a curing agent for an epoxy resin (phenol resin or the like), and a curing accelerator for an epoxy resin (imidazole compound or the like). As the binder, the thermoplastic resin and the thermosetting resin can be used alone or in combination of two or more, and preferably, the thermoplastic resin and the thermosetting resin are used in combination of two or more. A volume ratio of the binder in the magnetic composition is a remaining portion of a volume ratio of the magnetic particles to be described later.

The magnetic particles are, for example, dispersed in the binder. In the present embodiment, the magnetic particles have, for example, a generally flat shape. The generally flat shape includes a generally plate shape. The magnetic particles may have a generally spherical shape or a generally needle shape. Preferably, the magnetic particles have a generally flat shape.

When the magnetic particles have a generally flat shape, the lower limit of a flat ratio (flat degree) of the magnetic particles is, for example, 8, preferably 15, and the upper limit thereof is, for example, 500, preferably 450. The flat ratio is, for example, calculated as an aspect ratio obtained by dividing a median diameter of the magnetic particles by an average thickness of the magnetic particles.

The lower limit of the median diameter of the magnetic particles is, for example, 3.5 μm, preferably 10 μm, and the upper limit thereof is, for example, 200 μm, preferably 150 μm. When the magnetic particles have a generally flat shape, the lower limit of the average thickness of the magnetic particles is, for example, 0.1 μm, preferably 0.2 μm, and the upper limit thereof is, for example, 3.0 μm, preferably 2.5 μm.

Further, a material for the magnetic particles is a metal. Examples of the metal include magnetic bodies such as a soft magnetic body and a hard magnetic body. Preferably, from the viewpoint of ensuring excellent inductance, a soft magnetic body is used.

Examples of the soft magnetic body include a single metal body containing one kind of metal element in a state of a pure material and an alloy body which is a eutectic (mixture) of one or more kinds of metal element (first metal element) and one or more kinds of metal element (second metal element) and/or non-metal element (carbon, nitrogen, silicon, phosphorus, or the like). These may be used alone or in combination of two or more.

An example of the single metal body includes a metal single body consisting of only one kind of metal element (first metal element). The first metal element is, for example, appropriately selected from iron (Fe), cobalt (Co), nickel (Ni), and another metal element that can be included as the first metal element of the soft magnetic body.

Further, examples of the single metal body include an embodiment including a core including only one kind of metal element and a surface layer including an inorganic material and/or an organic material which modify/modifies a portion of or the entire surface of the core, and an embodiment in which an organic metal compound and an inorganic metal compound including the first metal element are decomposed (thermally decomposed or the like). More specifically, an example of the latter embodiment includes an iron powder (may be referred to as a carbonyl iron powder) in which an organic iron compound (specifically, carbonyl iron) including iron as the first metal element is thermally decomposed. The position of a layer including the inorganic material and/or the organic material modifying a portion including only one kind of metal element is not limited to the surface described above. The organic metal compound and the inorganic metal compound that can obtain the single metal body are not particularly limited, and can be appropriately selected from a known or conventional organic metal compound and inorganic metal compound that can obtain the single metal body of the soft magnetic body.

The alloy body is not particularly limited as long as it is a eutectic of one or more kinds of metal element (first metal element) and one or more kinds of metal element (second metal element) and/or non-metal element (carbon, nitrogen, silicon, phosphorus, or the like) and can be used as an alloy body of a soft magnetic body.

The first metal element is an essential element in the alloy body, and examples thereof include iron (Fe), cobalt (Co), and nickel (Ni). When the first metal element is Fe, the alloy body is referred to as a Fe-based alloy; when the first metal element is Co, the alloy body is referred to as a Co-based alloy; and when the first metal element is Ni, the alloy body is referred to as a Ni-based alloy.

The second metal element is an element (auxiliary component) which is auxiliarily included in the alloy body, and is a metal element which is compatible (eutectic) with the first metal element. Examples thereof include iron (Fe) (when the first metal element is other than Fe), cobalt (Co) (when the first metal element is other than Co), nickel (Ni) (when the first metal element is other than Ni), chromium (Cr), aluminum (Al), silicon (Si), copper (Cu), silver (Ag), manganese (Mn), calcium (Ca), barium (Ba), titanium (Ti), zirconium (Zr), hafnium (Hf), vanadium (V), niobium (Nb), tantalum (Ta), molybdenum (Mo), tungsten (W), ruthenium (Ru), rhodium (Rh), zinc (Zn), gallium (Ga), indium (In), germanium (Ge), tin (Sn), lead (Pb), scandium (Sc), yttrium (Y), strontium (Sr), and various rare earth elements. These may be used alone or in combination of two or more.

The non-metal element is an element (auxiliary component) which is auxiliarily included in the alloy body and is a non-metal element which is compatible (eutectic) with the first metal element, and examples thereof include boron (B), carbon (C), nitrogen (N), silicon (Si), phosphorus (P), and sulfur (S). These may be used alone or in combination of two or more.

Examples of the Fe-based alloy which is one example of an alloy body include magnetic stainless steel (Fe—Cr—Al—Si alloy) (including electromagnetic stainless steel), Sendust (Fe—Si—Al alloy) (including Supersendust), permalloy (Fe—Ni alloy), Fe—Ni—Mo alloy, Fe—Ni—Mo—Cu alloy, Fe—Ni—Co alloy, Fe—Cr alloy, Fe—Cr—Al alloy, Fe—Ni—Cr alloy, Fe—Ni—Cr—Si alloy, silicon copper (Fe—Cu—Si alloy), Fe—Si alloy, Fe—Si—B(—Cu—Nb) alloy, Fe—B—Si—Cr alloy, Fe—Si—Cr—Ni alloy, Fe—Si—Cr alloy, Fe—Si—Al—Ni—Cr alloy, Fe—Ni—Si—Co alloy, Fe—N alloy, Fe—C alloy, Fe—B alloy, Fe—P alloy, ferrite (including stainless steel-based ferrite, and furthermore, soft ferrite such as Mn—Mg-based ferrite, Mn—Zn-based ferrite, Ni—Zn-based ferrite, Ni—Zn—Cu-based ferrite, Cu—Zn-based ferrite, and Cu—Mg—Zn-based ferrite), Permendur (Fe—Co alloy), Fe—Co—V alloy, and Fe-based amorphous alloy.

Examples of the Co-based alloy which is one example of an alloy body include Co—Ta—Zr and a cobalt (Co)-based amorphous alloy.

An example of the Ni—based alloy which is one example of an alloy body includes a Ni—Cr alloy.

A more detailed formulation of the above-described magnetic composition is described in Japanese Unexamined Patent Publication No. 2014-165363 or the like.

The lower limit of a volume ratio of the magnetic particles in the magnetic composition is, for example, 40% by volume, preferably 50% by volume, more preferably 60% by volume, and the upper limit thereof is, for example, 95% by volume, preferably 90% by volume.

The lower limit of a thickness of the inductor 2 is, for example, 30 μm, preferably 40 μm, and the upper limit of the thickness of the inductor 2 is, for example, 2,500 μm, preferably 2,000 μm.

The lower limit of a ratio of the thickness of the inductor 2 to the thickness of the laminated sheet 13 is, for example, 0.1, preferably 0.3, more preferably 0.5, and the upper limit thereof is, for example, 0.9, preferably 0.8, more preferably 0.7.

The mark formable layer 15 is a layer which is capable of forming a mark 4 to be described next. That is, the mark formable layer 15 is a layer in which the mark 4 is not yet provided and is not a mark layer 3 in which the mark 4 is already provided. The mark formable layer 15 has a sheet shape extending in the plane direction. Specifically, the mark formable layer 15 has the same outer shape as the laminated sheet 13 when viewed from the top. The mark formable layer 15 is disposed on the one surface 9 of the magnetic layer 8. Specifically, the mark formable layer 15 is in contact with the entire one surface 9.

A material for the mark formable layer 15 is not particularly limited, and examples thereof include a resin composition, a metal, and ceramics, and preferably, a resin composition is used. When the material for the mark formable layer 15 is a resin composition, it is easy to form the mark 4 to be described next.

The resin composition contains, for example, a resin as an essential component and contains particles as an optional component.

Examples of the resin include curable resins such as a thermosetting resin and an active energy ray-curable resin, and plastic resins such as a thermoplastic resin.

As the curable resin, preferably, a thermosetting resin is used. Since when the thermosetting resin is used, the mark formable layer 15 can include a cured product of the thermosetting resin, a rate of change of the magnetic permeability of the laminated sheet 13 in an immersion test to be described next can be reduced. The thermosetting resin includes a main agent, a curing agent, and a curing accelerator.

Examples of the main agent include an epoxy resin and a silicone resin, and preferably, an epoxy resin is used. Examples of the epoxy resin include bifunctional epoxy resins such as a bisphenol A epoxy resin, a bisphenol F epoxy resin, a bisphenol S epoxy resin, a modified bisphenol A epoxy resin, a modified bisphenol F epoxy resin, a modified bisphenol S epoxy resin, and a biphenyl epoxy resin; and trifunctional or more polyfunctional epoxy resins such as a phenol novolac epoxy resin, a cresol novolac epoxy resin, a trishydroxyphenylmethane epoxy resin, a tetraphenylol ethane epoxy resin, and a dicyclopentadiene epoxy resin. These epoxy resins may be used alone or in combination of two or more. Preferably, a bifunctional epoxy resin is used, more preferably, a bisphenol A epoxy resin is used.

The lower limit of an epoxy equivalent of the epoxy resin is, for example, 10 g/eq., and the upper limit thereof is, for example, 1,000 g/eq.

When the main agent is the epoxy resin, examples of the curing agent include a phenol resin and an isocyanate resin. Examples of the phenol resin include polyfunctional phenol resins such as a phenol novolac resin, a cresol novolac resin, a phenol aralkyl resin, a phenol biphenylene resin, a dicyclopentadiene phenol resin, and a resol resin. These may be used alone or in combination of two or more. As the phenol resin, preferably, a phenol novolac resin and a phenol biphenylene resin are used. When the main agent is the epoxy resin and the curing agent is the phenol resin, the lower limit of the total sum of hydroxyl groups in the phenol resin is, for example, 0.7 equivalents, preferably 0.9 equivalents, and the upper limit thereof is, for example, 1.5 equivalents, preferably 1.2 equivalents with respect to 1 equivalent of epoxy groups in the epoxy resin. Specifically, the lower limit of the number of parts by mass of the curing agent is, for example, 1 part by mass, and the upper limit thereof is, for example, 50 parts by mass with respect to 100 parts by mass of the main agent.

The curing accelerator is a catalyst (thermosetting catalyst) which promotes curing of the main agent (preferably, epoxy resin curing accelerator), and examples thereof include an organic phosphorus compound, and an imidazole compound such as 2-phenyl-4-methyl-5-hydroxymethylimidazole (2P4MHZ). The lower limit of the number of parts by mass of the curing accelerator is, for example, 0.05 parts by mass, and the upper limit thereof is, for example, 5 parts by mass with respect to 100 parts by mass of the main agent.

Examples of the thermoplastic resin include an acrylic resin, a polyester resin, and a thermoplastic polyurethane resin. Further, as the thermoplastic resin, a hydrophilic polymer is also used.

As the resin, any of a curable resin and a plastic resin can be used alone, or they can be used in combination of two or more.

The lower limit of a mass ratio of the resin in the resin composition is, for example, 10% by mass, preferably 30% by mass, and the upper limit thereof is, for example, 90% by mass, preferably 75% by mass.

The particles are at least one kind selected from the group consisting of first particles and second particles.

The first particles have, for example, a generally spherical shape. The lower limit of the median diameter of the first particles is, for example, 1 μm, preferably 5 μm, and the upper limit of the median diameter of the first particles is, for example, 250 μm, preferably 200 μm. The median diameter of the first particles is determined with a laser diffraction particle size distribution measuring device. The median diameter of the first particles can be also determined, for example, by binarization process by cross-sectional observation.

A material for the first particles is not particularly limited. Examples of the material for the first particles include metals, an inorganic compound, an organic compound, and a single body of a non-metal element, and from the viewpoint of reliably forming the mark 4, preferably, an inorganic compound and a single body of a non-metal element are used.

The inorganic compound is included in the resin composition when the mark formable layer 15 functions as an ink receiving layer. An example of the inorganic compound includes an inorganic filler, and specifically, silica and alumina are used, preferably, silica is used.

The single body of a non-metal element is included in the resin composition when the mark formable layer 15 functions as a laser discoloration layer. Examples of the single body of a non-metal element include carbon and silicon, and preferably, carbon is used, more preferably, carbon black is used.

Specifically, as the first particles, preferably, spherical silica is used, and preferably, spherical carbon black is used.

The second particles have, for example, a generally flat shape, The generally flat shape includes a generally plate shape.

The lower limit of a flat ratio (flat degree) of the second particles is, for example, 8, preferably 15, and the upper limit thereof is, for example, 500, preferably 450. The flat ratio of the second particles is determined by the same calculation method as the flat ratio of the magnetic particles in the magnetic layer 8 described above.

The lower limit of the median diameter of the second particles is, for example, 1 μm, preferably 5 μm, and the upper limit of the median diameter of the second particles is, for example, 250 μm, preferably 200 μm. The median diameter of the second particles is determined in the same manner as that of the first particles.

The lower limit of the average thickness of the second particles is, for example, 0.1 μm, preferably 0.2 82 m, and the upper limit thereof is, for example, 3.0 μm, preferably 2.5 μm.

A material for the second particles is an inorganic compound. An example of the inorganic compound includes a thermally conductive compound such as boron nitride.

Specifically, as the second particles, preferably, a flat-shaped boron nitride is used.

One kind or both of the first particles and the second particles are included in the resin composition.

The lower limit of the number of parts by mass of the particles (first particles and/or second particles) is, for example, 10 parts by mass, preferably 50 parts by mass, and the upper limit thereof is, for example, 2,000 parts by mass, preferably 1,500 parts by mass with respect to 100 parts by mass of the resin. Further, the lower limit of a content ratio of the particles in the resin composition is, for example, 10% by mass, and the upper limit thereof is, for example, 90% by mass. When both of the first particles and the second particles are included in the resin composition, the lower limit of the number of parts by mass of the second particles is, for example, 30 parts by mass, and the upper limit thereof is, for example, 300 parts by mass with respect to 100 parts by mass of the first particles.

Since the particles are an optional component in the resin composition, the resin composition may not include the particles.

The lower limit of a thickness of the mark formable layer 15 is, for example, 1 μm, preferably 10 μm, and the upper limit thereof is, for example, 1,000 μm, preferably 100 μm. The lower limit of a ratio of the thickness of the mark formable layer 15 in the thickness of the laminated sheet 13 is, for example, 0.001, preferably 0.005, more preferably 0.01, and the upper limit thereof is, for example, 0.5, preferably 0.3, more preferably 0.1.

The lower limit of a thickness of the laminated sheet 13 is, for example, 40 μm, preferably 50 μm, and the upper limit of the thickness of the inductor 2 is, for example, 3,000 μm, preferably 2,500 μm.

Next, a method for producing the above-described laminated sheet 1, and a processing embodiment thereof are described with reference to FIGS. 1A to 2D.

In this method, first, as shown in FIG. 2A, the inductor 2 is prepared. The inductor 2 is prepared by, for example, a method described in Japanese Unexamined Patent Publication No. 2019-220618 or the like.

Next, in this method, as shown in FIGS. 1A and 2B, the mark formable layer 15 is disposed on one surface in the thickness direction of the inductor 2.

To dispose the mark formable layer 15 in the inductor 2, first, a mark formable sheet 14 is prepared. The mark formable sheet 14 is a sheet before the mark formable layer 15 is disposed with respect to the one surface 9 of the inductor 2, and a material thereof is the same as that of the mark formable layer 15. To prepare the mark formable sheet 14, a solvent is further blended into the above-described material to prepare a varnish, and the obtained varnish is applied to the surface of a release sheet (not shown) to be dried. When the resin contains a thermosetting resin, the thermosetting resin is in a B—stage state or a C-stage state.

Subsequently, the mark formable sheet 14 is attached to one surface in the thickness direction of the inductor 2. Specifically, the other surface in the thickness direction of the mark formable sheet 14 is brought into contact with one surface in the thickness direction of the inductor 2. Thus, the mark formable sheet 14 is formed in the mark formable layer 15 in a state of being in contact with the one surface 9 of the magnetic layer 8. Or, the mark formable layer 15 can be also formed by applying the varnish directly to the one surface 9 of the inductor 2.

Thereafter, when the resin contains a thermosetting resin in a B-stage state, the thermosetting resin is brought into a C-stage state by heating.

Thus, the mark formable layer 15 is disposed (laminated) on one surface in the thickness direction of the inductor 2. Preferably, the mark formable layer 15 adheres to the one surface 9 of the magnetic layer 8.

Thus, the laminated sheet 13 including the inductor 2, and the mark formable layer 15 is obtained. The laminated sheet 13 preferably includes only the inductor 2 and the mark formable layer 15.

The laminated sheet 13 is not yet provided with the mark 4, and includes the mark formable layer 15 for forming the mark 4, and is an industrially available device which can be distributed alone.

The laminated sheet 13 satisfies, for example, at least one test of the test (a) to test (e).

Test (a): the laminated sheet 13 is trimmed into a 3 cm square piece to fabricate a sample, and the relative permeability μl thereof at a frequency of 10 MHz is determined. Thereafter, the sample is immersed in 200 mL of copper sulfate plating solution containing 66 g/L of copper sulfate pentahydrate, 180 g/L of sulfuric acid concentration, 50 ppm of chlorine, and Top Lutina alpha manufactured by Okuno Chemical Industries Co., Ltd. at 25° C. for 120 minutes, and thereafter, the relative permeability μ2 of the sample at a frequency of 10 MHz is determined. By the following formula, a rate of change of the magnetic permeability before and after the immersion is determined. As a result, the rate of change of the magnetic permeability of the sample is 5% or less.

Rate of Change of Magnetic Permeability (%)=|μ1-μ2|/μ1×100

Test (b): the laminated sheet 13 is trimmed into a 3 cm square piece to fabricate a sample, and the relative permeability μ3 thereof at a frequency of 10 MHz is determined. Thereafter, the sample is immersed in 200 mL of an acid active aqueous solution containing 55 g/L of sulfuric acid at 25° C. for 1 minute, and thereafter, the relative permeability μ4 of the sample at a frequency of 10 MHz is determined. By the following formula, a rate of change of the magnetic permeability before and after the immersion is determined. As a result, the rate of change of the magnetic permeability of the sample is 5% or less.

Rate of Change of Magnetic Permeability (%)=|μ3-μ4|/μ3×100

Test (c): the laminated sheet 13 is trimmed into a 3 cm square piece to fabricate a sample, and the relative permeability μ5 thereof at a frequency of 10 MHz is determined. Thereafter, the sample is immersed in 200 mL of Reduction Solution Securiganth P manufactured by Atotech Japan K.K. at 45° C. for 5 minutes, and thereafter, the relative permeability μ6 of the sample at a frequency of 10 MHz is determined. By the following formula, a rate of change of the magnetic permeability before and after the immersion is determined. As a result, the rate of change of the magnetic permeability of the sample is 5% or less.

Rate of Change of Magnetic Permeability (%)=|μ5-μ6|/μ5×100

Test (d): the laminated sheet 13 is trimmed into a 3 cm square piece to fabricate a sample, and the relative permeability μ7 thereof at a frequency of 10 MHz is determined. Thereafter, the sample is immersed in 200 mL of Concentrate Compact CP manufactured by Atotech Japan K.K. at 80° C. for 15 minutes, and thereafter, the relative permeability μ8 of the sample at a frequency of 10 MHz is determined. By the following formula, a rate of change of the magnetic permeability before and after the immersion is determined. As a result, the rate of change of the magnetic permeability of the sample is 5% or less.

Rate of Change of Magnetic Permeability (%)=|μ7-μ8|/μ7×100

Test (e): the laminated sheet 13 is trimmed into a 3 cm square piece to fabricate a sample, and the relative permeability μ9 thereof at a frequency of 10 MHz is determined. Thereafter, the sample is immersed in 200 mL of Swelling Dip Securiganth P manufactured by Atotech Japan K.K. at 60° C. for 5 minutes, and thereafter, the relative permeability μ10 of the sample at a frequency of 10 MHz is determined. By the following formula, a rate of change of the magnetic permeability before and after the immersion is determined. As a result, the rate of change of the magnetic permeability of the sample is 5% or less.

Rate of Change of Magnetic Permeability (%)=|μ9-μ10|/μ9×100

When the test (a) is satisfied, the upper limit of the rate of change of the magnetic permeability of the sample in the test (a) is preferably 4%, more preferably 3%.

When the test (a) is satisfied, the laminated sheet 13 is excellent in stability with respect to the immersion of the copper sulfate solution of the electrolytic copper plating.

When the test (b) is satisfied, the upper limit of the rate of change of the magnetic permeability of the sample in the test (b) is preferably 4%, more preferably 3%.

When the test (b) is satisfied, the laminated sheet 13 is excellent in stability with respect to the immersion of the acid active solution.

When the test (c) is satisfied, the upper limit of the rate of change of the magnetic permeability of the sample in the test (c) is preferably 4%, more preferably 3%.

Reduction Solution Securiganth P manufactured by Atotech Japan K.K. in the test (c) includes a sulfuric acid aqueous solution, and is used as a neutralizing solution (neutralizing agent or an aqueous solution for neutralization). Therefore, when the test (c) is satisfied, the laminated sheet 13 is excellent in stability with respect to the immersion of the neutralizing solution.

When the test (d) is satisfied, the upper limit of the rate of change of the magnetic permeability of the sample in the test (d) is preferably 4%, more preferably 3%.

Concentrate Compact CP manufactured by Atotech Japan K.K. in the test (d) includes a potassium permanganate solution. Therefore, when the test (d) is satisfied, the laminated sheet 13 is excellent in stability with respect to the immersion of the potassium permanganate solution of desmear (cleaning).

When the test (e) is satisfied, the upper limit of the rate of change of the magnetic permeability of the sample in the test (e) is preferably 4%, more preferably 3%.

Swelling Dip Securiganth P manufactured by Atotech Japan K.K. in the test (e) is an aqueous solution containing glycol ethers and sodium hydroxide, and is used as a swelling solution. Therefore, when the test (e) is satisfied, the laminated sheet 13 is excellent in stability with respect to the immersion of the swelling solution.

Preferably, all of the test (a) to test (e) are satisfied. Therefore, the laminated sheet 13 is excellent in stability with respect to the immersion of the copper sulfate solution of the electrolytic copper plating, the acid active solution, the neutralizing solution, the potassium permanganate solution of the desmear (cleaning), and the swelling solution, and is excellent in stability with respect to various processes using these solutions.

Thereafter, as shown in FIGS. 1B and 2C, for example, the mark 4 is formed in the mark formable layer 15.

A forming method of the mark 4 is not particularly limited, and examples thereof include drilling and etching.

The mark 4 is, for example, a mark for notifying the positional information of the plurality of wirings 7 in the laminated sheet 13. The mark 4 is an alignment mark for forming a via 16 to be described next in the laminated sheet 13.

The mark 4 is formed in the mark formable layer 15. Specifically, the mark 4 is disposed on one surface in the thickness direction of the mark formable layer 15. Each of the marks 4 is, for example, formed in each four corner portion 6 partitioned by the four sides 5 of the mark formable layer 15. The mark 4 has, for example, a generally cross shape when viewed from the top.

Further, the mark 4 is a recessed portion that proceeds from one surface in the thickness direction of the mark formable layer 15 toward the other side in the thickness direction to the middle in the thickness direction.

Further, the mark 4 is separated outwardly in a direction in which the plurality of wirings 7 are adjacent to each other when projected in the thickness direction. That is, the mark 4 is not overlapped with the plurality of wirings 7 when projected in the thickness direction, and deviates with respect to the plurality of wirings 7. The lower limit of the shortest distance L between the mark 4 and the wiring 7 is, for example, 10 μm, preferably 50 μm, and the upper limit thereof is, for example, 10 mm, preferably 5 mm, more preferably 3 mm.

A dimension of the mark 4 is not particularly limited. The lower limit of a length of the mark 4 in a direction in which the wiring 7 extends is, for example, 10 μm, preferably 50 μm, and the upper limit thereof is, for example, 5 mm, preferably 1 mm. The lower limit of the length of the mark 4 in a direction in which the plurality of wirings 7 are adjacent to each other is, for example, 10 μm, preferably 50 μm, and the upper limit thereof is, for example, 5 mm, preferably 1 mm.

The lower limit of a depth of the mark 4 is, for example, 1 μm, preferably 5 μm, and the upper limit thereof is 1 mm. The lower limit of a ratio of the depth of the mark 4 to the thickness (depth) of the mark layer 3 is, for example, 0.01, preferably 0.1, and the upper limit thereof is, for example, 0.9, preferably 0.7.

Therefore, the mark formable layer 15 becomes the mark layer 3 in which the mark 4 is formed. Therefore, a mark-including laminated sheet 1 including the inductor 2, the mark layer 3, and the mark 4 is obtained.

As shown in FIGS. 1C and 2D, thereafter, the via 16 is, for example, formed in the mark-including laminated sheet 1.

In the formation of the via 16, for example, the mark 4 is used as an alignment mark to align the mark-including laminated sheet 1. For example, the position in the plane direction of the mark-including laminated sheet 1 with respect to a device for carrying out the next processing is adjusted with the mark 4 as a reference.

The forming method of the via 16 is not particularly limited and examples thereof include contact-type opening using drilling and non-contact-type processing using a laser.

The via 16 is, for example, overlapped with the mark 4 when projected in a direction in which the wirings 7 are adjacent to each other, and is overlapped with the wiring 7 when viewed from the top. Specifically, the via 16 is a through hole which exposes the central portion of one surface in the thickness direction of the wiring 7 and penetrates the magnetic layer 8 and the mark layer 3 in the thickness direction located on one side in the thickness direction with respect to the wiring 7. The via 16 has a generally circular shape when viewed from the top (not shown). The via 16 also has a tapered shape in which the opening area expands toward one side in the thickness direction when viewed in the cross-sectional view.

Thereafter, the mark-including laminated sheet 1 in which the via 16 is formed is, for example, subjected to steps such as photolithography and plating (copper plating etc.), and an electrically conductive layer which is not shown is formed in the wiring 7 exposed from the via 16 to be mounted and bonded to an electronic device or an electronic component. The electronic device or the electronic component is electrically connected to the wiring 7 through the via 16.

<Function and Effect of One Embodiment>

Then, the laminated sheet 13 includes the mark formable layer 15. Therefore, when the mark 4 is formed in the mark formable layer 15, it is possible to form the via 16 by aligning the mark-including laminated sheet 1 based on the mark 4.

Furthermore, in the laminated sheet 13, when the material for the mark formable layer 15 is the resin composition, it is easy to form the mark 4.

Furthermore, since the laminated sheet 13 satisfies, for example, at least one test of the test (a) to test (e), it is excellent in stability with respect to process processing using a chemical solution.

<Modified Examples>

In the following modified examples, the same reference numerals are provided for members and steps corresponding to each of those in the above-described one embodiment, and their detailed description is omitted. Further, each of the modified examples can achieve the same function and effect as that of one embodiment unless otherwise specified. Furthermore, one embodiment and the modified examples thereof can be appropriately used in combination.

A shape of the mark 4 is not limited to the description above. Although not shown, examples of the shape of the mark 4 include a generally V-shape, a generally L-shape, a generally X-shape, a generally I-shape (including a generally linear shape), a generally U-shape, a generally C-shape, a generally circular ring shape (including a generally elliptical ring shape), a generally circular shape (including a generally elliptical shape), a generally polygonal frame shape (including a generally triangular frame shape and a generally rectangular frame shape), and a generally polygonal shape (including a generally triangular shape and a generally rectangular shape).

The position of the mark 4 is not particularly limited, and for example, though not shown, the mark 4 may be located between the wirings 7 adjacent to each other.

As shown in FIG. 3, the mark formable layer 15 may be a laser discolorable layer and/or an ink receptable layer.

When the mark formable layer 15 is a laser discolorable layer, the laser discolorable layer includes, for example, a thermosetting resin as a resin and spherical carbon black as the first particles, and has, for example, a black color. When the laser is applied to the laser discolorable layer, the first particles (carbon black) in the applied portion are thermally decomposed and removed, and the blackness of the portion becomes low (the color becomes pale) (discolored). Thus, the mark formable layer 15 becomes the mark layer 3 having the discolored mark 4.

When the mark formable layer 15 is an ink receptable layer, the ink receptable layer includes, for example, a hydrophilic polymer as a resin and spherical silica as the first particles. An ink (not shown) is printed on the ink receptable layer, and thereafter, the hydrophilic polymer and the silica of the ink receptable layer absorb (have affinity to) the ink. Thus, the mark formable layer 15 becomes the mark layer 3 having the colored mark 4.

As shown in FIG. 4, the mark 4 may penetrate the mark formable layer 15.

As shown in FIG. 5, the mark 4 may be also disposed on one surface in the thickness direction of the mark formable layer 15. The mark 4 is made of, for example, a solid material of the ink (preferably, a cured product such as an ultraviolet curable product).

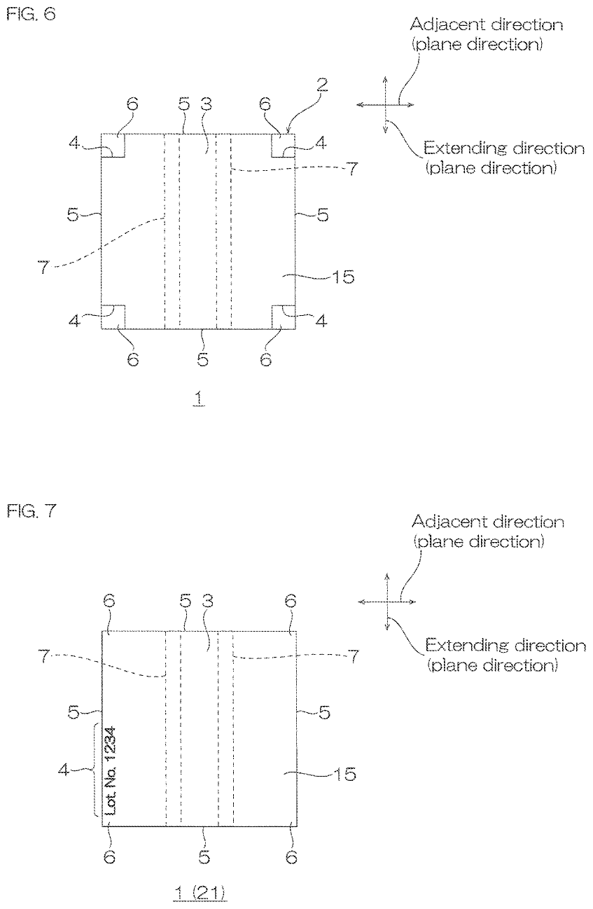

As shown in FIG. 6, the mark 4 cuts out the corner portion 6 of the mark formable layer 15 (ref: FIG. 6). The mark 4 cuts out the corner portion 6 into a rectangular shape in the thickness direction.

As shown in FIG. 7, the mark 4 may also include information about the laminated sheet 13 as a product instead of or together with the alignment mark. Examples of the information include the lot number of the laminated sheet 13 and the magnetic permeability of the laminated sheet 13.

In the modified example shown by a dashed line of FIG. 2B, the mark formable layer 15 is disposed on the one surface 9 and the other surface 10 of the inductor 2. In the modified example, as shown in FIG. 2C, the mark 4 is formed on each of the two mark formable layers 15.

An electrically conductive layer (not shown) can be also formed in the via 16. Examples of a material for the electrically conductive layer (not shown) include conductive materials such as copper. In the formation of the electrically conductive layer, for example, an electrolytic copper plating solution is used. Thus, the mark-including laminated sheet 1 including the electrically conductive layer (not shown) is obtained.

While the illustrative embodiments of the present invention are provided in the above description, such is for illustrative purpose only and it is not to be construed as limiting the scope of the present invention. Modification and variation of the present invention that will be obvious to those skilled in the art is to be covered by the following claims.

### DESCRIPTION OF SYMBOLS

2 Inductor

7 Wiring

8 Magnetic layer

13 Laminated sheet

15 Mark formable layer

1. A laminated sheet comprising:
a sheet-shaped inductor including a plurality of wirings and a magnetic layer embedding the plurality of wirings, and
a mark formable layer disposed on one surface in a thickness direction of the inductor.

2. The laminated sheet according to claim 1, wherein
a material for the mark formable layer is a resin composition.

3. The laminated sheet according to claim 2, wherein the resin composition is a thermosetting resin composition, and satisfies at least one test of the following test (a) to test (e):
Test (a): the laminated sheet is trimmed into a 3 cm square piece to fabricate a sample, and the relative permeability μ1 thereof at a frequency of 10 MHz is determined. Thereafter, the sample is immersed in 200 mL of copper sulfate plating solution containing 66 g/L of copper sulfate pentahydrate, 180 g/L of sulfuric acid concentration, 50 ppm of chlorine, and Top Lutina alpha at 25° C. for 120 minutes, and thereafter, the relative permeability μ2 of the sample at a frequency of 10 MHz is determined. By the following formula, a rate of change of the magnetic permeability before and after the immersion is determined. As a result, the rate of change of the magnetic permeability of the sample is 5% or less.
Rate of Change of Magnetic Permeability (%)=|μ1-μ2|/μ1×100
Test (b): the laminated sheet is trimmed into a 3 cm square piece to fabricate a sample, and the relative permeability μ3 thereof at a frequency of 10 MHz is determined. Thereafter, the sample is immersed in 200 mL of an acid active aqueous solution containing 55 g/L of sulfuric acid at 25° C. for 1 minute, and thereafter, the relative permeability μ4 of the sample at a frequency of 10 MHz is determined. By the following formula, a rate of change of the magnetic permeability before and after the immersion is determined. As a result, the rate of change of the magnetic permeability of the sample is 5% or less.
Rate of Change of Magnetic Permeability (%)=|μ3-μ4|/μ3×100
Test (c): the laminated sheet is trimmed into a 3 cm square piece to fabricate a sample, and the relative permeability μ5 thereof at a frequency of 10 MHz is determined. Thereafter, the sample is immersed in 200 mL of Reduction Solution Securiganth P manufactured by Atotech Japan K.K. at 45° C. for 5 minutes, and thereafter, the relative permeability μ6 of the sample at a frequency of 10 MHz is determined. By the following formula, a rate of change of the magnetic permeability before and after the immersion is determined. As a result, the rate of change of the magnetic permeability of the sample is 5% or less.
Rate of Change of Magnetic Permeability (%)=|μ5-μ6|/μ5×100
Test (d): the laminated sheet is trimmed into a 3 cm square piece to fabricate a sample, and the relative permeability μ7 thereof at a frequency of 10 MHz is determined. Thereafter, the sample is immersed in 200 mL of Concentrate Compact CP manufactured by Atotech Japan K.K. at 80° C. for 15 minutes, and thereafter, the relative permeability μ8 of the sample at a frequency of 10 MHz is determined. By the following formula, a rate of change of the magnetic permeability before and after the immersion is determined. As a result, the rate of change of the magnetic permeability of the sample is 5% or less.
Rate of Change of Magnetic Permeability (%)=|μ7-μ8|/μ7×100
Test (e): the laminated sheet is trimmed into a 3 cm square piece to fabricate a sample, and the relative permeability μ9 thereof at a frequency of 10 MHz is determined. Thereafter, the sample is immersed in 200 mL of Swelling Dip Securiganth P manufactured by Atotech Japan K.K. at 60° C. for 5 minutes, and thereafter, the relative permeability μ10 of the sample at a frequency of 10 MHz is determined. By the following formula, a rate of change of the magnetic permeability before and after the immersion is determined. As a result, the rate of change of the magnetic permeability of the sample is 5% or less.
Rate of Change of Magnetic Permeability (%)=|μ9-μ10|/μ9×100
